(19) United States
(12) Patent Application Publication
(10) Pub. No.: US 2009/0085162 A1
(43) Pub. Date: Apr. 2, 2009

(54) SEMICONDUCTOR DEVICE AND INTEGRATED SEMICONDUCTOR CIRCUIT DEVICE

(75) Inventors: Atsushi Kurokawa, Tokyo (JP); Kenji Sasaki, Tokyo (JP); Isao Obu, Tokyo (JP); Satoshi Suzuki, Tokyo (JP)

Correspondence Address: MCDERMOTT WILL & EMERY LLP, 600 13TH STREET, N.W., WASHINGTON, DC, 20005-3096, US

(73) Assignees: RENESAS TECHNOLOGY CORP.; MITSUBISHI ELECTRIC CORPORATION

(21) Appl. No.: 12/237,648

(22) Filed: Sep. 25, 2008

(30) Foreign Application Priority Data
Sep. 28, 2007 (JP) 2007-255317

(51) Int. Cl. H01L 29/73

(52) U.S. Cl. 257/565; 257/E29.174

(57) ABSTRACT

The present invention provides a semiconductor device that includes a plurality of transistor cells and makes it possible to achieve higher degree of integration and lower cost of an integrated semiconductor circuit device as the first object, and provide an integrated semiconductor circuit device of high density integration and compact construction at a low cost.

The semiconductor device includes a plurality of transistor cells each comprising the first layer, the base layer and the second layer formed in this order on the substrate, one of the first layer and the second layer serving as the collector layer and the other serving as the emitter layer, and the first electrode connected to the first layer of each of the transistor cells is formed in the etching trench formed in the first layer, wherein the etching trench has normal mesa surface on the side thereof in the longitudinal direction, and the first electrodes of the plurality of transistor cells are connected each other through a collective wiring that is provided so as to cross the normal mesa surfaces of the trenches of the plurality of transistor cells.

### BACKGROUND OF THE INVENTION

1. Field of the Invention

The present invention relates to a semiconductor device constituted from a plurality of transistor cells and to an integrated semiconductor circuit device that includes the semiconductor device.

2. Description of the Related Art

FIG. 13 is a sectional view of a compound semiconductor bipolar transistor cell 1′ which exemplifies the conventional transistor cell. This well-known transistor is manufactured as follows. First, a sub-collector layer 20, a collector layer 30, a base layer 40, an emitter layer 50 and an upper emitter layer 60 are formed by epitaxial growth on a compound semiconductor substrate 10. After processing the emitter layer 50, the base layer 40, etc. into desired shapes, an etching trench 35′, through which the sub-collector layer 20 is exposed, is formed by partially wet-etching the collector layer 30, and a collector electrode 130 is formed in the etching trench 35′.

When the collector electrode is formed by forming the etching trench, it is necessary to design the transistor cell structure by taking into consideration the crystal orientation dependency of the etching rate, as will be described later. For example, wet etching of GaAs that is a III-V group compound semiconductor results in an etched-out space having cross section of normal mesa shape (or mesa shape) perpendicular to crystal orientation [01-1] (direction of −X in FIG. 12(a) and FIG. 12(b)) in terms of Miller indices as shown in FIG. 12(a) and FIG. 12(b). The cross section of the etched-out space rotated by 90 degrees, namely the cross section perpendicular to crystal orientation [011] (direction of −Y in FIG. 12(c) and FIG. 12(d)) has inverted mesa shape (or reverse mesa shape) as shown in FIG. 12(c) and FIG. 12(d). It is known that many compound semiconductors represented by GaAs have crystal orientation dependency, and that the cross section thereof becomes mesa shape and inverted mesa shape.

Negative signs of Miller indices are described herein as prefix before the related numbers such as [−1−1−1], while the negative sign is described on top of the related number in the conventional notation of the Miller indices.

When a lead-out wiring is formed on the inverted mesa surface, wire breakage or the like tends to occur. As a result, presence of the inverted mesa surface imposes restriction on the layout of lead-out wiring from the collector electrode or the emitter electrode provided in the etching trench. Accordingly, the conventional transistor cell 1′ has been formed in such a structure as shown in FIG. 10.

In the transistor cell 1′, the etching trench 35′ has a shape of normal mesa on both ends thereof (normal mesa surface), and lead-out wirings 135′ are formed on the normal mesa surface (FIG. 10(b)). While a cross section perpendicular to the longitudinal direction of the etching trench 35′ of the transistor cell 1′ has inverted mesa shape (side face along the longitudinal direction is inverted mesa surface) (refer to FIG. 13), this does not pose a problem since no lead-out wiring is formed on this surface.

However, in a transistor cell 1″ having such a configuration that the transistor cell 1′ is rotated by 90 degrees, although the cross section perpendicular to the longitudinal direction of the etching trench 35″ has normal mesa shape, the cross section of the etching trench 35″ has inverted mesa shape (inverted mesa surface) as shown in FIG. 11(b).

As a result, in the transistor cell 1″ having such a configuration that the transistor cell 1′ is rotated by 90 degrees as shown in FIG. 11(a), the lead-out wire 135″ is formed on the inverted mesa surface, which may cause crack or the like in the portion that is bent in wedge shape (portion C′ of FIG. 11(b)), thus resulting in conduction failure such as wire breakage or increasing electrical resistance.

Accordingly, since the etching trench of the conventional transistor cell 1′ shown in FIG. 10(a) is required to have an end face forming normal mesa shape in the longitudinal direction of the etching trench, longitudinal direction of the etching trench is restricted in a single direction (normal mesa direction (which will be described in detail later)).

In the conventional transistor cell 1′, as described above, it is necessary to form the etching trench always in a particular direction. As a result, orientation of the transistor cell (basic transistor cell) is also restricted and therefore pattern layout of the integrated semiconductor circuit device formed by integrating the transistor cells is restricted, thereby making it difficult to increase the degree of integration and manufacture the device in smaller construction at a lower cost.

To counter these problems, for example, Bob Yeats et al.; 2000 GaAsMANTECH 131-135 (2000) discloses a technique whereby the inverted mesa formed on the end face of the collector layer in the longitudinal direction of the etching trench is smoothed. By adding the smoothing process, it is made possible to employ the transistor cell 1′ shown in FIG. 10(a) in a layout of rotating by 90 degrees.

However, the method disclosed by Bob Yeats et al. requires it to introduce the new process of smoothing, and therefore has problems of lower productivity and increasing manufacturing cost.

### SUMMARY OF THE INVENTION

Accordingly a first object of the present invention is to provide a semiconductor device that includes a plurality of transistor cells and makes it possible to achieve higher degree of integration and lower cost of an integrated semiconductor circuit device, a second object of the present invention is to provide an integrated semiconductor circuit device of high degree of integration and compact construction at a lower cost.

The present invention achieves the objects described above, by providing such a compact transistor cell structure that includes etching trench having longitudinal direction that is perpendicular to the longitudinal direction of the etching trench of the conventional transistor cell 1′, and enables it to form collective wiring on the normal mesa surface of the etching trench.

Specifically a first semiconductor device according to the present invention includes a plurality of transistor cells each comprising a first layer, a base layer and a second layer formed in this order on a substrate, one of the first layer and the second layer serving as a collector layer and the other serving as an emitter layer, and a first electrode connected to the first layer of each of the transistor cells is formed in an etching trench that is formed in the first layer, wherein the etching trench has normal mesa surface on the side along the longitudinal direction thereof, and the first electrodes of the plurality of transistor cells are connected each other through a collective wiring that is provided so as to cross the normal mesa surfaces of said trenches of said plurality of transistor cells.

A second semiconductor device according to the present invention includes a plurality of transistor cells each having a first layer, a base layer and a second layer formed in this order on a substrate, one of the first layer and the second layer serving as a collector layer and the other serving as an emitter layer, and first electrode connected to the first layer of each of the transistor cells is formed in an etching trench that is formed in the first layer, wherein the etching trenches formed between adjacent transistor cells are connected each other through a second etching trench formed in the first layer, and the first electrode formed between the plurality of transistor cells are connected each other through a second electrode provided in the second etching trench.

The present invention makes it possible to provide a semiconductor device having transistor cells disposed in such a direction that is 90 degrees from the direction of the conventional transistor cell in which it has been difficult to dispose transistor cells due to the difficulty in providing the lead-out wiring, without providing any additional process such as smoothing the inverted mesa.

As a result, the present invention provides a semiconductor device that includes a plurality of transistor cells that makes it possible to achieve a higher degree of integration and lower cost of the integrated semiconductor circuit device.

Use of the semiconductor device of the present invention makes it possible to increase the degree of freedom in the layout of the device and provide a compact integrated semiconductor circuit device with higher degree of integration at a lower cost.

### BRIEF DESCRIPTION OF THE DRAWINGS

FIG. 1 is a top view of the semiconductor device 250 according to the present invention.

FIG. 2A is a sectional view taken along lines IIA-IIA in FIG. 1.

FIG. 2B is a sectional view taken along lines IIB-IIB in FIG. 1.

FIG. 3 is a sectional view showing a method of manufacturing the transistor cells according to the present invention.

FIG. 4 is a top view of the semiconductor device 250A according to the present invention.

FIG. 5 is a sectional view taken along lines V-V in FIG. 4.

FIG. 6 is a circuit diagram of the integrated semiconductor circuit device 300 according to the present invention.

FIG. 7 is a plan view of the integrated semiconductor circuit device 300 according to the present invention.

FIG. 8 is a top view of the semiconductor device 320 used in the integrated semiconductor circuit device 300 according to the present invention.

FIG. 9 is a top view of the semiconductor device 330 used in the integrated semiconductor circuit device 300 according to the present invention.

FIG. 10(a) is a plan view of the conventional inverted mesa transistor cell 1′, and FIG. 10(b) is a sectional view taken along lines Xb-Xb in FIG. 10(a).

FIG. 11(a) is a plan view of the conventional normal mesa transistor cell 1″, and FIG. 11(b) is a sectional view taken along lines XIb-XIb in FIG. 11(a).

FIG. 12(a) is a plan view showing crystal orientation [01-1] of the semiconductor layer, FIG. 12(b) is a sectional view taken along lines XIIb-XIIb in FIG. 12(a), FIG. 12(c) is a plan view showing crystal orientation [011] of the semiconductor layer, and FIG. 12(d) is a sectional view taken along lines XIId-XIId in FIG. 12(c).

FIG. 13 is a sectional view of the conventional semiconductor cell 1′.

FIG. 14 is a top view of the conventional semiconductor device 250′.

FIG. 15 is a top view of the conventional semiconductor device 250″.

FIG. 16(a) is a sectional view taken along lines XVIa-XVIa in FIG. 15, and FIG. 16(b) is a sectional view taken along lines XVIb-XVIb in FIG. 15.

FIG. 17 is a top view of the conventional semiconductor device 260.

FIG. 18 is a plan view of the conventional integrated semiconductor circuit device 300′.

FIG. 19 is a top view of the semiconductor device 320′ of the conventional integrated semiconductor circuit device 300′.

### DETAILED DESCRIPTION OF THE INVENTION

Embodiments of the present invention will be described in detail below with reference to the accompanying drawings. In the description that follows, terms that mean particular directions or positions (such as up, down, right, left, and phrases that include such terms) are used. Use of the terms is intended to help understand the present invention with reference to the accompanying drawings, and should not be interpreted to restrict the scope of the present invention. Identical reference numerals shown in the drawings denote identical parts or members.

### 1. EMBODIMENT OF SEMICONDUCTOR DEVICE

### First Embodiment

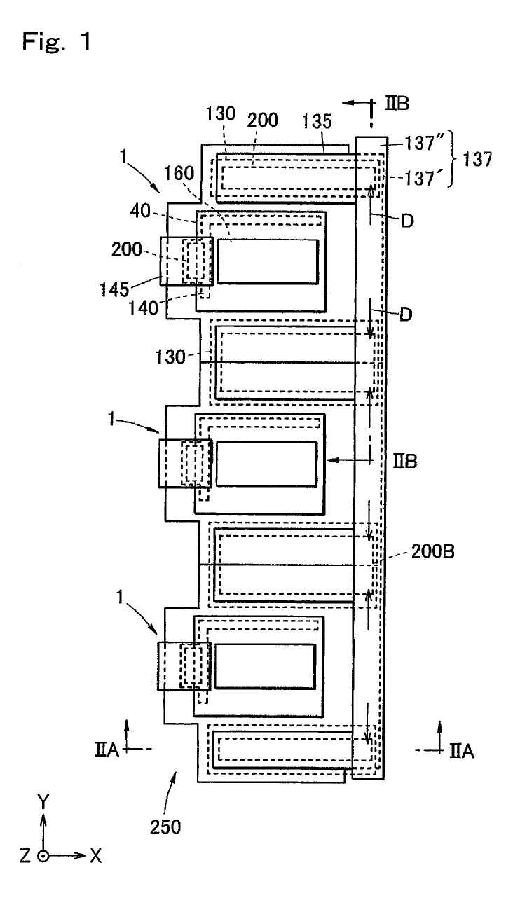

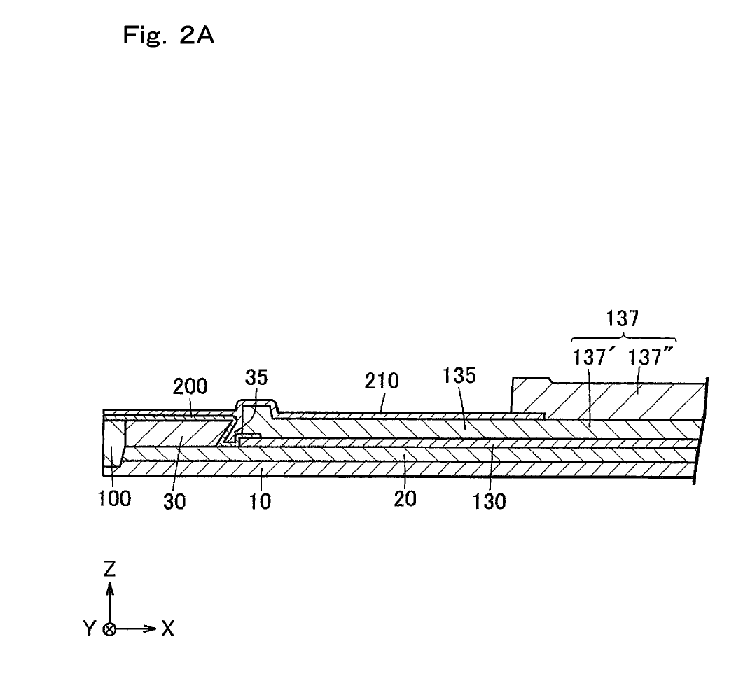

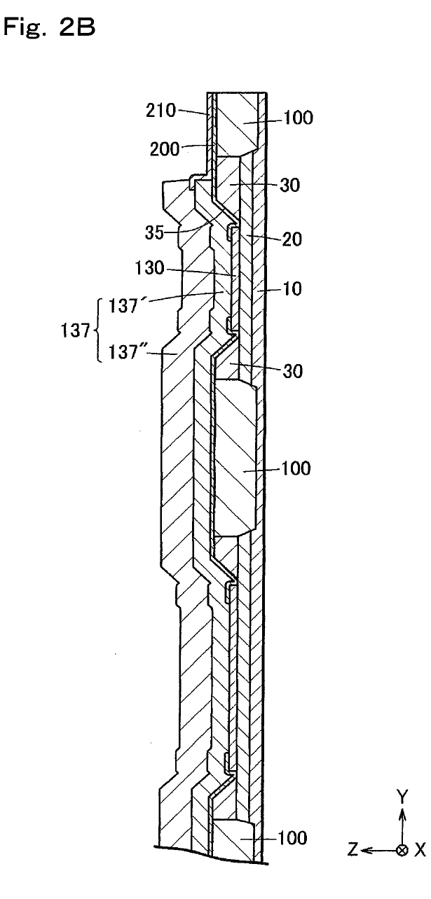

FIG. 3(a) to FIG. 3(f) are sectional views showing a method of manufacturing heterojunction bipolar transistors (HBT) cell 1 according to the first embodiment, that is an example of the transistor cell of the present invention. FIG. 1 is a top view of a semiconductor device 250 that includes the bipolar transistors 1. FIG. 2A is a sectional view taken along lines IIA-IIA in FIG. 1, and FIG. 2B is a sectional view taken along lines IIB-IIB in FIG. 1.

In the transistors cell of the first embodiment, longitudinal direction of the etching trench formed in the collector layer is set to inverted mesa direction (the direction in which the end face of the etching trench in the longitudinal direction has inverted mesa shape), contrary to conventional transistor cells. Collector electrodes provided between a plurality of transistor cells are connected by a collective wiring provided to cross a side face that is formed as normal mesa surface along the longitudinal direction of the etching trench. This constitution prevents electrical conduction failure (or disconnection) that might occur when lead-out wiring is provided along the end face of the etching trench in the longitudinal (the end face that is formed in inverted mesa shape), as in the conventional way.

Thus according to the first embodiment, the etching trench and the collector electrode disposed in the etching trench are formed to extend longer than the emitter electrode. Then the collective wiring which is connected with collector electrodes provided between a plurality of transistor cells is disposed so as to cross the side face of the etching trench that runs along the longitudinal direction of the etching trench and is normal mesa surface, and electrical connection between the collective wiring and the first electrode (i.e. collector electrode in the case of the embodiment of FIG. 1) is established at this crossing. This structure makes it possible to provide a semiconductor device that greatly reduces the risk of electrical conduction failure.

A compound semiconductor heterojunction bipolar transistor 1 according to the first embodiment of the present invention will be described in detail below with reference to the accompanying drawings.

### Process for Manufacturing Heterojunction Bipolar Transistor 1 According to First Embodiment

A sub-collector layer 20 of high-concentration n-type GaAs with thickness of about 0.5 μm, a collector layer 30 of n-type GaAs with thickness of 0.5 to 1.5 μm, a base layer 40 of p-type GaAs with thickness of 0.05 to 0.15 μm, an emitter layer 50 of n-type InGaP and an upper emitter layer 60 of GaAs and InGaAs are formed in this order on a compound semiconductor substrate 10 of GaAs.

The sub-collector layer 20 decreases the ohmic resistance and serves as a collector together with the collector layer 30. The upper emitter layer 60 may also be formed, for example, in a stacked structure of GaAs layer, InₓGa₁₋ₓAs layer and In_{0.5}Ga_{0.5}As layer.

Then an emitter electrode 160 is formed from, for example, WSi, and a portion of the upper emitter layer 60 that is not covered by the emitter electrode 160 is etched till the emitter layer 50 is exposed (the state shown in FIG. 3(a)). Principal surfaces of the emitter electrode 160 and the upper emitter layer 60 located below thereof have rectangular shape that extends in a direction parallel to X axis as can be seen from FIG. 1.

Then after providing an atomic isolation injection region 100 so as to insulate the bipolar transistor 1 from the surrounding area (FIG. 3(b)), a base electrode 140 is formed in contact with the base layer 40 (FIG. 3(c)). The base electrode 140 is preferably formed by stacking Au, Ti and Pt layers.

Then the base semiconductor layer 40 and the collector layer 30 are etched away to a depth of about 0.1 to 0.4 μm from the top, so as to form a base-collector junction (base mesa) region (FIG. 3(d)).

Then after etching the collector layer 30 down to the sub-collector region 20 by wet etching so as to form the etching trench 35, the collector electrode (first electrode) 130 that is preferably formed by stacking Au, Ni and AuGe layers is formed at the bottom of the etching trench 35 by lift-off process (FIG. 3(e)).

The etching trench 35 has a shape of rectangular parallelepiped extending in the X axis direction so as to be capable of accommodating the collector electrode 130 that extends in the X axis direction, similarly to the emitter electrode 160 and the upper emitter layer 60. The etching trench 35 has cross section perpendicular to the extending direction (the surface parallel to Y-Z plane shown in FIG. 1 and FIG. 3) of normal mesa shape (refer to FIG. 3(e)), and the side surface along the direction parallel to the X axis is normal mesa surface. The etching trench 35 also has cross section parallel to the extending direction and perpendicular to the principal surface of the collector layer 30 (the surface parallel to X-Z plane shown in FIG. 1 and FIG. 3) of inverted mesa shape (refer to FIG. 2A).

According to the present invention, the sectional shape of the etching trench 35 described above is achieved by making the direction in which the etching trench 35 extends (longitudinal direction (direction of X axis shown in FIG. 1 and FIG. 3)) parallel to crystal orientation [01-1] of the collector layer 30 made of GaAs, and making the direction that is perpendicular to the direction in which the etching trench 35 extends and is parallel to the principal surface of the collector layer 30 (direction of Y axis shown in FIG. 1 and FIG. 3) parallel to crystal orientation [011] of the collector layer 30.

Then a protective insulator film 200 is formed, and the lead-out wiring 135 composed of the first wiring layer having thickness of, for example, 1 to 2 μm is formed by lift-off process, thereby forming the transistor cell 1 (refer to FIG. 3(f)). Opening 200B of the protective insulator film 200 provided on adjacent collector electrodes are combined into one large opening (refer to FIG. 1).

Then a second protective insulator film 210 and a second wiring layer 137″ are formed as shown in FIG. 2A and FIG. 2B. The collective wiring 137 is provided in the form of double layers in the embodiment shown in FIGS. 2A and 2B, consisting of a first wiring 137′ and a second wiring 137″ placed on top thereof.

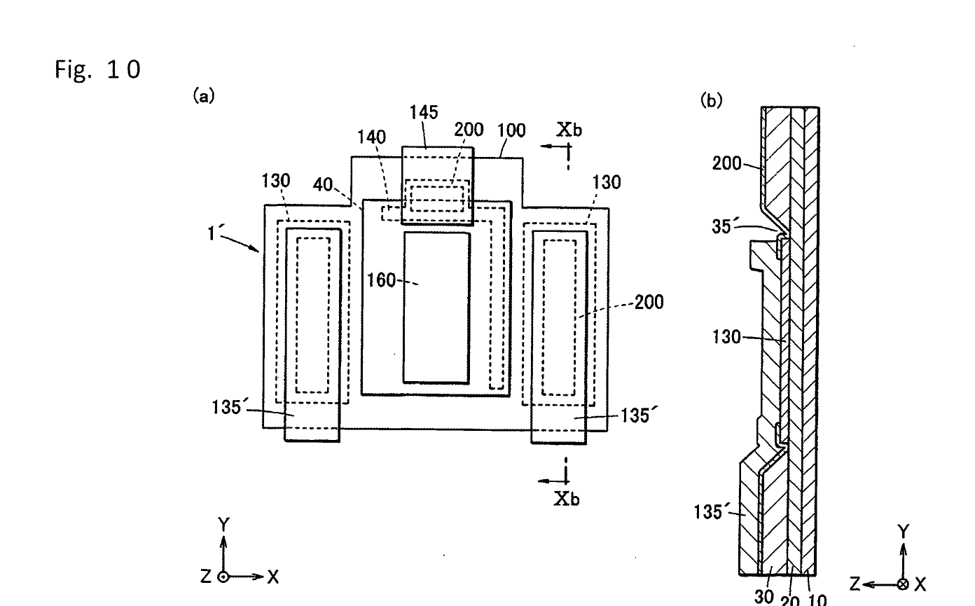

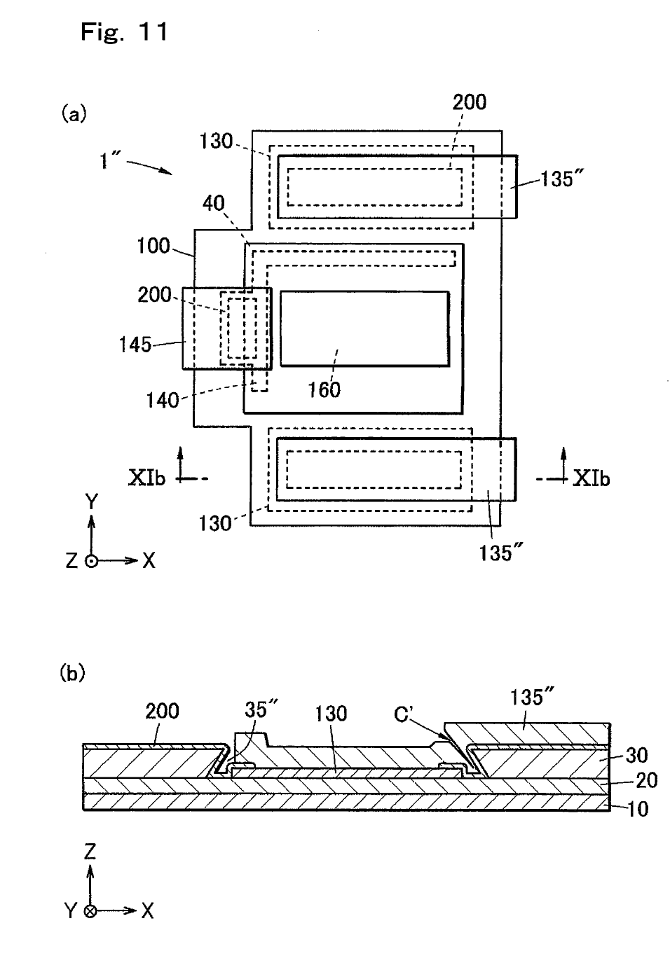

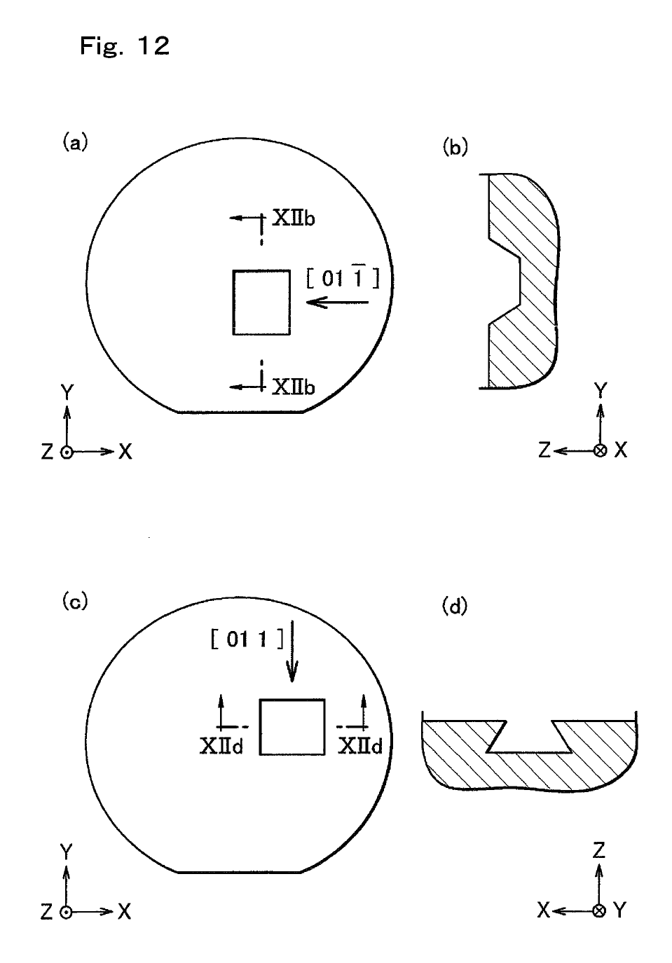

In case the etching trench 35′ has normal mesa structure on the end face thereof in the longitudinal direction as shown in FIG. 10(a) and FIG. 10(b), direction in which the etching trench extends is referred to herein as the normal mesa direction.

The transistor (transistor cell) in which the etching trench 35′ that extends in the normal mesa direction is provided and the etching trench 35′ has cross section of inverted mesa shape perpendicular to the longitudinal direction will be called inverted mesa transistor (inverted mesa transistor cell). The direction in which the etching trench extends is referred to the normal mesa direction.

On the other hand, as shown in FIG. 1 and FIG. 2A, in case the etching trench 35 has end face of inverted mesa structure in the longitudinal direction, direction in which the etching trench extends will be called the inverted mesa direction.

The transistor (transistor cell) in which the etching trench 35 extending in the inverted mesa direction is provided and the etching trench 35 has cross section of normal mesa shape perpendicular to the longitudinal direction thereof will be called normal mesa transistor (normal mesa transistor cell).

Crystallographic orientations of the normal mesa direction and the inverted mesa direction vary depending on the type of semiconductor.

A semiconductor device 250 formed by disposing a plurality of bipolar basic transistor cells 1 in the same direction will be described below in detail. For the ease of understanding, a conventional semiconductor device 250′ comprising a plurality of inverted mesa bipolar basic transistor cells 1 and a semiconductor device 250″ having constitution similar to that of the semiconductor 250′ by using normal mesa bipolar transistor will be described.

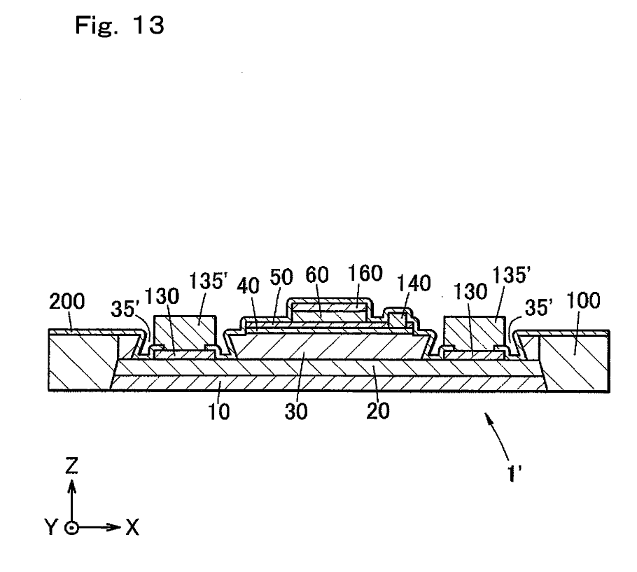

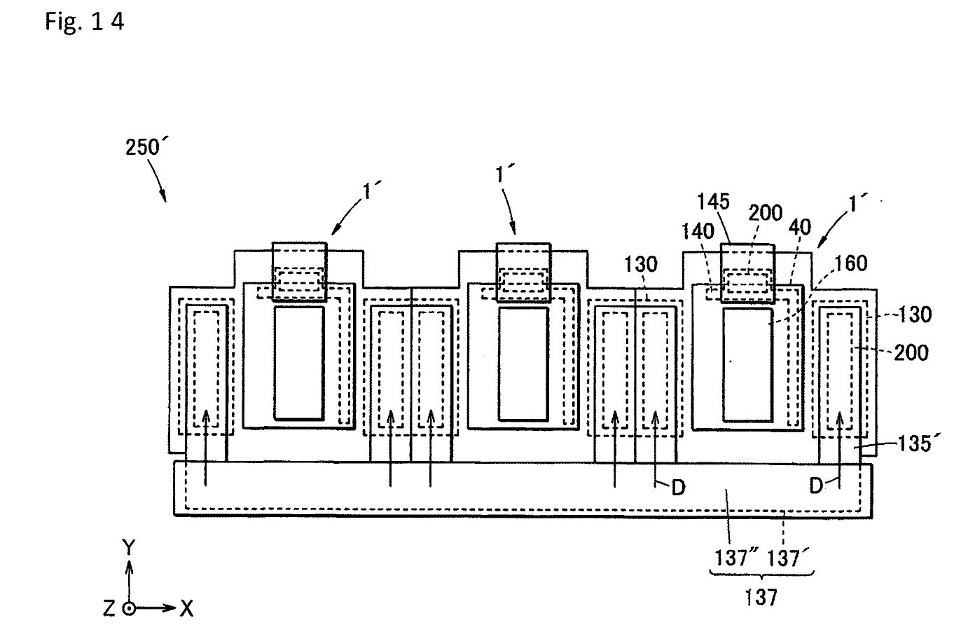

FIG. 14 is a top view of the semiconductor device 250′ that has three inverted mesa bipolar basic transistor cells 1′ disposed in the same direction. Two etching trenches 35′ (refer to FIG. 10(b) and FIG. 13, not shown in FIG. 14) of each basic transistor cell 1′ extend in parallel to [011] orientation of the collector layer, namely in the normal mesa direction. As a result, there is lower risk of electrical conduction failure such as wire breakage of the lead-out wiring 135′ that passes the end face of the etching trench 35′ in the longitudinal direction thereof and comes out of the etching trench.

In order to electrically connect the lead-out wirings 135′ between adjacent transistor cells 1′, the collective wiring 137 is provided to run in a direction perpendicular to the direction in which the etching trench 35′ extends. The collective wiring 137 is disposed so as to contact with part of the lead-out wirings 135′ of the transistor cells 1′ of FIG. 10 that is not housed in the etching trench 35′ when viewed from above (part that is parallel to X axis in FIG. 14).

The collective wiring 137 may also be formed solely from a collective wiring 137′, by extending the first wiring layer which is same as lead-out wiring 135′. Also the second wiring layer may be placed as a collective wiring 137″ on top of the collective wiring 137′, so that a larger current can be carried as required. The first wiring layer and the second wiring layer are formed, for example, by stacking Au, Ti layers by lift-off process.

Collector current flowing in the collective wiring 137 is carried by the lead-out wiring 135′ along arrow D and reaches the collector electrode 130. In the semiconductor device 250′, however, only the inverted mesa bipolar transistor cell can be used, and therefore all the basic transistors are disposed in the same direction, or in a direction rotated by 180 degrees in the principal plane (substantially the same direction in terms of the layout).

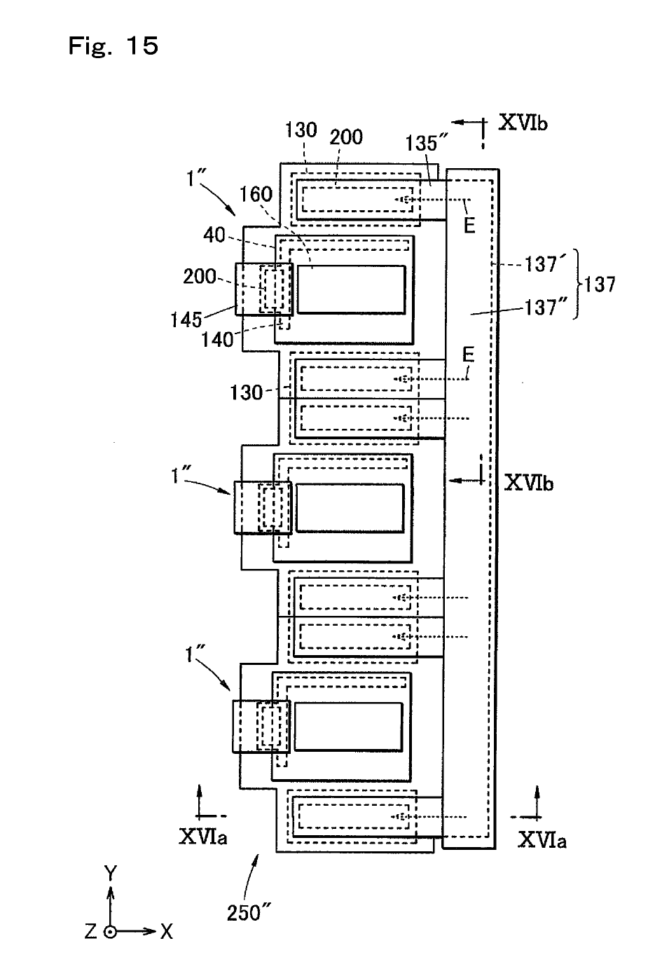

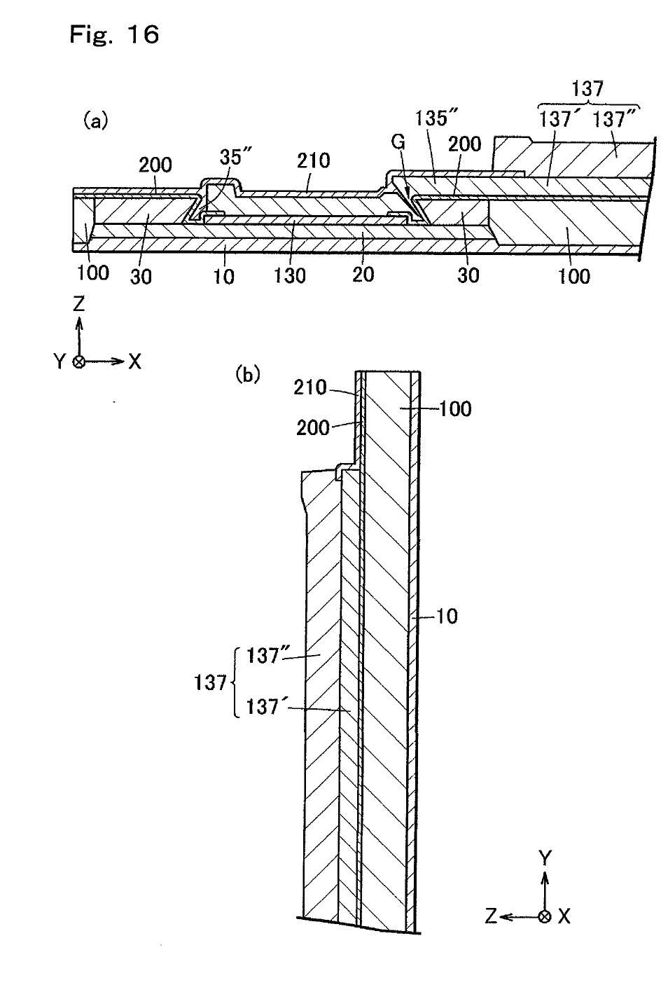

FIG. 15 is a top view of the semiconductor device 250″ that has three normal mesa bipolar basic transistor cells 1″ disposed in the same direction. The semiconductor device 250″ shown in FIG. 15 is constituted by forming the collector electrode 130 and the collective wiring 137 in patterns similar to FIG. 14. FIG. 16(a) and FIG. 16(b) are sectional views along lines XVIa-XVIa and XVIb-XVIb shown in FIG. 15, respectively. Two etching trenches 35″ of the basic transistor cells 1″ (refer to FIG. 16(a)) extend in parallel to [01-1] orientation of the collector layer 30, namely in the inverted mesa direction.

As a result, as shown in FIG. 16(a), the lead-out wiring 135′ that runs from the top of the collector electrode 130 passing along the end face (formed in inverted mesa shape) in the direction in which the etching trench extends and comes out of the etching trench 35″ bends in a wedge shape in the portion indicated by arrow G, thus posing the risk of electrical conduction failure such as wire breakage. Thus it is difficult to stably conduct the collector current from the collective wiring 137 through the lead-out wiring 135″ along arrow E in FIG. 15 to the collector electrode 130, and it can be seen that such a structure of collective wiring cannot be employed. The collective wiring 137 shown in FIG. 16(a) has such a structure as the collective wiring 137″ consisting of the second wiring layer is placed on top of the collective wiring 137′ of the first wiring layer.

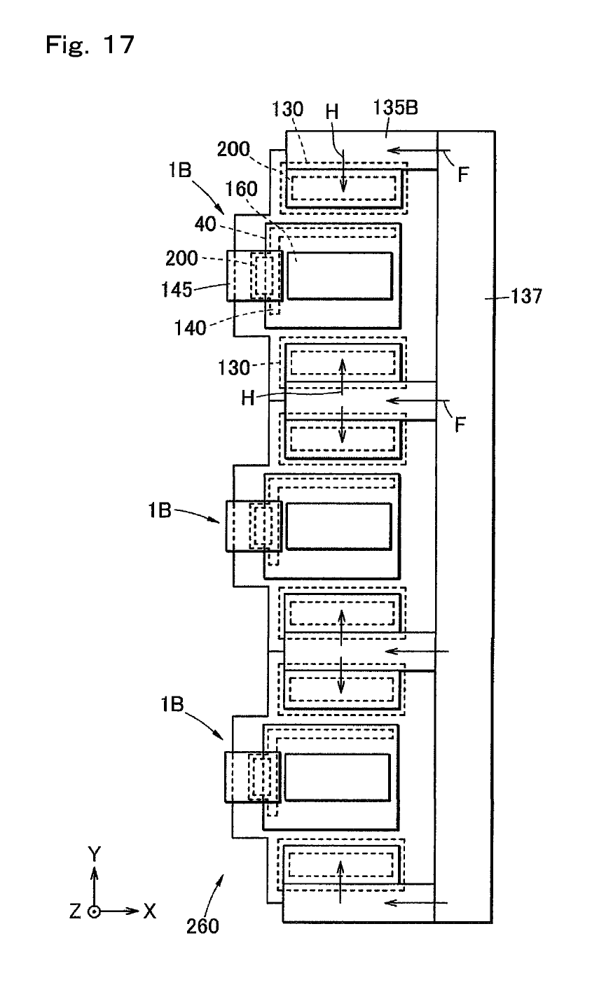

To solve this problem, the semiconductor device 260 shown in FIG. 17 has been employed. In the transistor cell 1B of the semiconductor device 260, the lead-out wiring 135B is disposed to run from the collector electrode 130 along the side wall of the etching trench 35″ that constitutes a normal mesa shape and is formed in the longitudinal direction of the etching trench 35″ (Y direction in FIG. 17), and is lead out of the etching trench 35″. For the connection with the lead-out wiring, the lead-out wiring 135B is provided with a portion extending out of the trench that extends in parallel to the etching trench 35″ (collector electrode 130) (in X direction of FIG. 17).

In the semiconductor device 260, the collector current can be conducted from the collective wiring 137 through the lead-out wiring 135B along arrow F and arrow H to the collector electrode 130, without causing the trouble of electrical conduction failure.

However, the portion extending out of the trench of the lead-out wiring 135B needs to have a width usually from 5 to 10 μm (Y direction in FIG. 17), and the space between the bipolar basic transistor cells 1B increases by this width. This means an increase in the required area over the case where the inverted mesa bipolar basic transistor cells are employed, and runs counter to the object of the present invention to provide an integrated semiconductor circuit device with reduced area.

The semiconductor device 250 according to the first embodiment of the present invention will be described in detail below. The transistor cell 1 has the etching trench 35 with cross section (Y-Z plane) perpendicular to the extending direction of the etching trench (X direction) of normal mesa shape, similarly to the transistor cell 1″.

However, the basic transistor cell 1 is different from the basic transistor cell 1″, in that the etching trench 35 and the collector electrode 130 extend to the bottom of the collective wiring 137 (refer to FIG. 2A and FIG. 16(a)). It can be carried out within the conventional process, to extend the etching trench 35 and the collector electrode 130.

With this constitution, among the end faces of inverted mesa shape in the direction in which the etching trench 35 extends in the cross section shown in FIG. 2A (plane parallel to the direction in which the etching trench 35 extends and perpendicular to the principal surface of the collector layer 30), the end face on the right-hand side (the side of X direction in FIG. 2A) is located to the right of the collective wiring 137 (further to the right (X direction) than the area shown in FIG. 2A).

The collective wiring 137 extends in a direction perpendicular to the direction in which the etching trench 35 extends. As a result, in the direction along which the collective wiring 137 extends (direction of −Y in FIG. 1), the etching trench 35 has normal mesa surface on the side thereof along the longitudinal direction as shown in FIG. 2B. Since the collective wiring 137 and the lead-out wiring 135 cross the normal mesa surface and the collector electrode 130 is connected, conduction failure due to wire breakage or the like can be suppressed from occurring in the semiconductor device 250.

In the constitution shown in FIG. 2B, the collective wiring 137 is formed by placing the collective wiring 137″ of the second wiring layer on top of the collective wiring 137′ of the first wiring layer. The collective wiring 137 is connected to the collector electrode via the lead-out wiring 135 consisting of the first wiring layer. The collective wiring 137 has such a structure as the collective wiring 137′ and the collective wiring 137″ are placed one on another, and therefore has an advantage of an increased current carrying capacity in the direction along which the collective wiring 137 extends. However, the collective wiring 137 may also comprise the collective wiring 137′ of the first wiring layer only, without providing the collective wiring 137″ of the second wiring layer.

As a result, use of the normal mesa bipolar transistor cells 1 makes it possible to provide the semiconductor device 250 with a low risk of continuity failure and small area similarly to the semiconductor device 250′ that uses the conventional inverted mesa bipolar transistor cell, even when the normal mesa bipolar transistor is used.

Thus it is possible to simultaneously use bipolar transistors that are disposed in directions different by 90 degrees, by using both the semiconductor device 250′ that uses the inverted mesa bipolar transistor and the semiconductor device 250 that uses the normal mesa bipolar transistor within the same integrated semiconductor circuit device that is formed on a substrate. That is, it is possible to provide the integrated semiconductor circuit device of smaller area that allows for a higher degree of freedom in the layout of the semiconductor devices.

### Second Embodiment

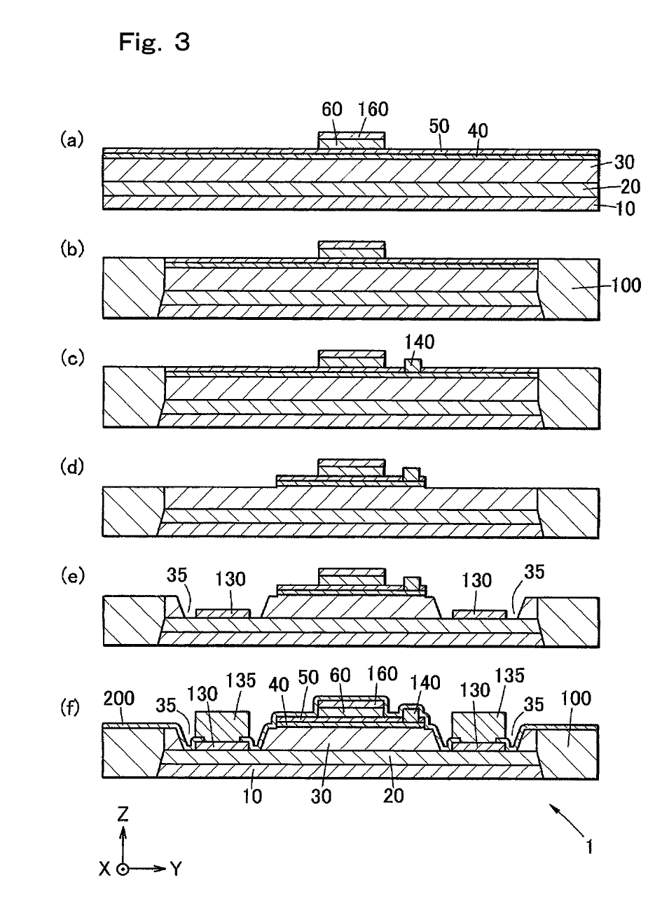

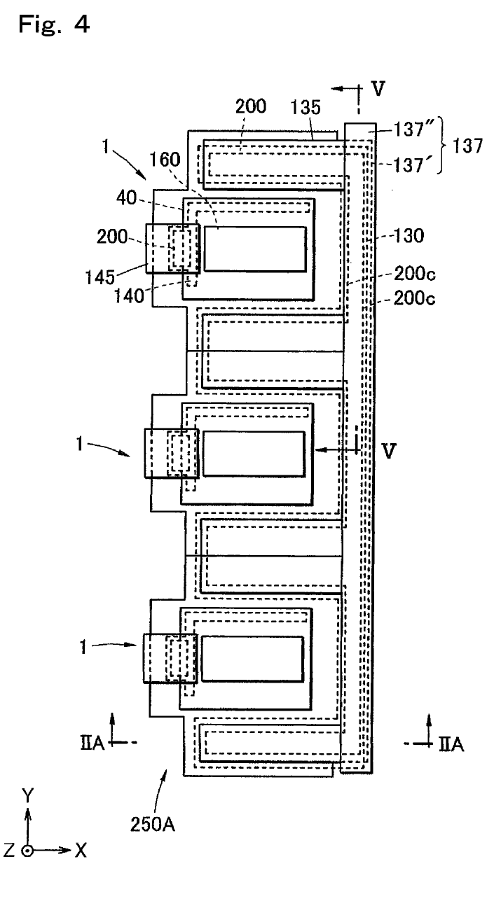

FIG. 4 is a top view of semiconductor device 250A according to the second embodiment of the present invention. FIG. 5 is a sectional view taken along lines V-V in FIG. 4. A section taken along lines IIa-IIa in FIG. 4 is the same as the section taken along lines IIa-IIa (FIG. 2A) of the semiconductor device 250 of the first embodiment shown in FIG. 1.

In the semiconductor device 250A, unlike the semiconductor device 250, the etching trench 35 and the collector electrode 130 extend not only in the longitudinal direction of the emitter electrode 160 provided in the etching trench (X direction in FIG. 4) as the first etching trench and the first electrode, but also in the direction parallel to the collective wiring 137 (Y direction in FIG. 4 and FIG. 5) as the second etching trench and the second electrode in the lower portion of the collective wiring 137. Openings 200C of the protective insulator film 200 provided on the collector electrodes may be combined into one large opening so that electrical conductivity with the collective wiring 137 and the like can be established more easily (refer to FIG. 4).

It can be done within the conventional process to extend the etching trench 35 and the collector electrode 130, simply by altering the area in which etching of the etching trench 35 and lift-off of the collector electrode 130 are carried out.

As shown in FIG. 5, the collective wiring 137 does not pass the upper portion of the side face of the etching trench 35, except at the end thereof. In FIG. 5, the collective wiring 137 has such a structure as the collective wiring 137″ of the second wiring layer is placed on top of the collective wiring 137′ of the first wiring layer. The collective wiring 137 may comprise only the first wiring layer or the second wiring layer, as required.

Thus the risk of electrical conduction failure can be decreased even when the side face of the etching trench 35 along the longitudinal direction of the emitter electrode 160 (X axis direction of FIG. 4 and FIG. 5) does not formed a normal mesa shape.

Therefore, the bipolar basic transistor cell 1 of the semiconductor device 250A according to the second embodiment may be either normal mesa bipolar basic transistor cell or inverted mesa bipolar basic transistor cell. Moreover, it may be a bipolar transistor cell disposed in any direction within a plane parallel to the semiconductor substrate 10.

Use of the semiconductor device 250A makes it possible to further increase the degree of freedom in the layout of the semiconductor devices that employ a plurality of bipolar transistor cells disposed in the same direction, within the integrated semiconductor circuit device, and reduce the area of the integrated semiconductor circuit device.

In the embodiment shown in FIG. 5, while portions of the collective wiring 137 and the collector electrode that extend in Y direction are provided as the second electrode that connects the portions (first electrode) of the collector electrode 130 parallel to the longitudinal direction of the emitter electrode 160, the collective wiring 137 may be omitted as required.

### 2. EMBODIMENT OF INTEGRATED SEMICONDUCTOR CIRCUIT DEVICE

### Third Embodiment

The integrated semiconductor circuit device that employs the semiconductor device 250 described above will be described in detail below.

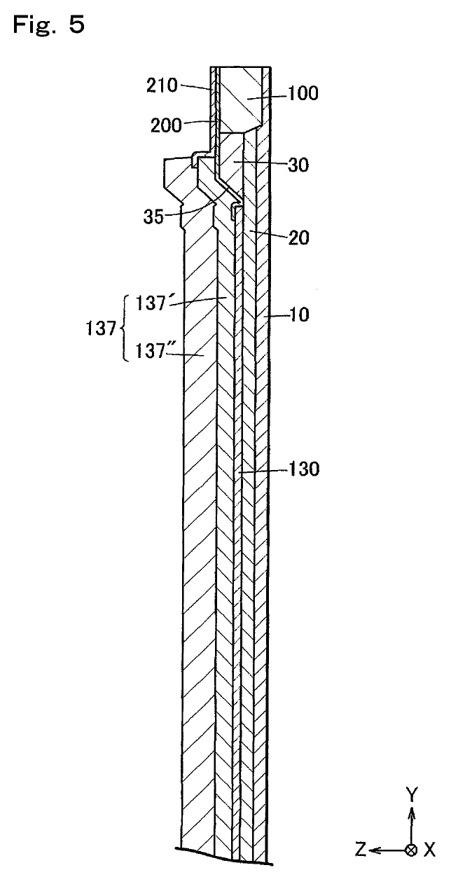

FIG. 6 is a circuit diagram of the integrated semiconductor circuit device according to the third embodiment, that includes two amplifier circuits comprising 3-stage heterojunction bipolar transistors (HBT). One of the amplifier circuits functions in a Lo band of operating frequencies around 0.9 GHz, and the other functions in a Hi band of operating frequencies around 1.8 GHz.

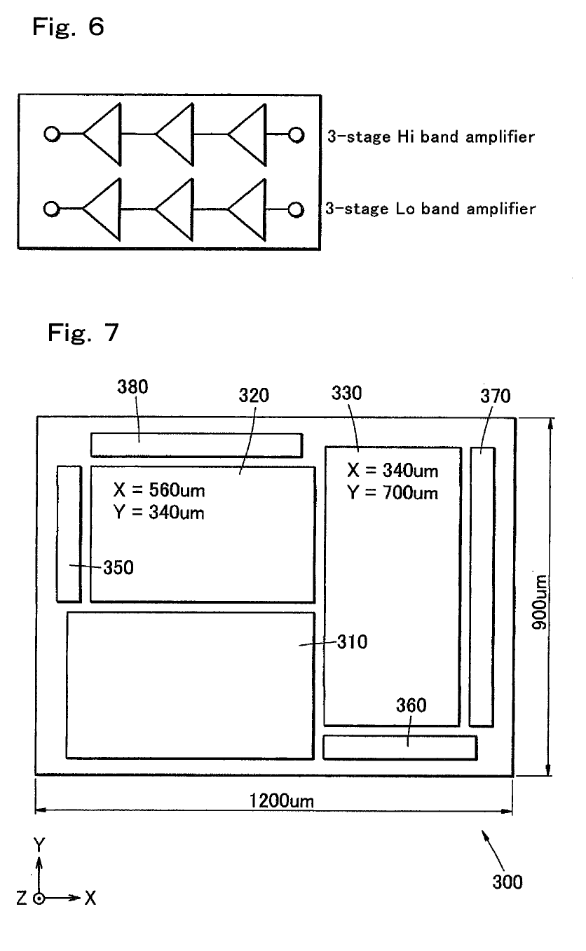

FIG. 7 is a plan view of integrated semiconductor circuit device 300 according to the present invention. The semiconductor device 310 has a plurality of HBTs that constitute the first stage amplifier and the second stage amplifier of Lo band, and a plurality of HBTs that constitute the first stage amplifier and the second stage amplifier of Hi band.

In the 3-stage amplifiers, small current flows in the first stage and the second stage in both the Lo band and Hi band, and the number of HBTs in the first stage is roughly from one to 2, and around 6 to 10 in the second stage, and therefore the first stage and the second stage of both bands can be accommodated in the semiconductor device 310.

The third stage transmits a high power, and 60 HBTs are required for the Lo band that are disposed over the semiconductor device 330 measuring 340 μm in X direction and 700 μm in Y direction. The third stage of Hi band requires 48 HBTs for the Hi band that are disposed over the semiconductor device 320 measuring 560 μm in X direction and 340 μm in Y direction.

Besides the above, the integrated semiconductor circuit device 300 includes a passive element 1 (reference numeral 350), a passive element 2 (reference numeral 360), a collector pad 380 for the semiconductor device 320 and a collector pad 370 for the semiconductor device 320, which are small in area and do not impose restriction on the layout.

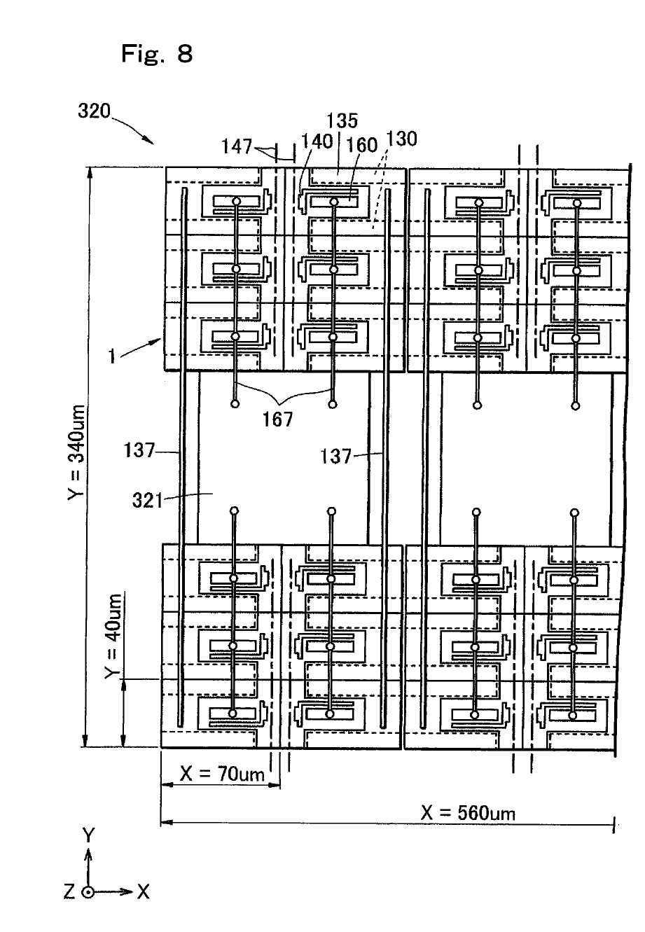

FIG. 8 is a top view showing the detail of the HBT (heterojunction bipolar transistor) disposed in the semiconductor device 320. The constitution is the same as that of the semiconductor device 250. The HBTs used in the semiconductor device 320 are normal mesa heterojunction bipolar transistor cells 1. The HBT 1 of the third embodiment has dimensions of 70 μm in X direction and 40 μm in Y direction that are one of standard sets of dimensions for HBT.

Six HBTs 1, three on one side and three on the other side of via hole electrode 321, are disposed in the Y direction in the drawing. Besides the collective wiring 137 for the collector current, the collective wiring 147 for the base current and the collective wiring 167 for the emitter current are also provided and are electrically connected to the base electrode 140 and the emitter electrode 160, respectively.

The first and second columns counting from the left end (from the proximal end in X direction) in FIG. 8 share the same via hole electrode 321 in common. The HBTs 1 of both the first and second columns are HBTs of normal mesa type, although the HBT 1 in the second column is rotated by 180 degrees from the position of the HBT 1 in the first column with the collective wirings 147 for the base current thereof being located near to each other.

Thus four sets in total, each set comprising two HBTs 1, namely eight HBTs 1 are disposed in the transverse direction (X direction) (only a part of which are shown in FIG. 8). In total, 48 HBTs 1 are disposed.

The via hole electrode 321 has dimensions of 100 μm in X direction and 100 μm in Y direction, with emitter collective wiring 167 being connected. The via hole electrode 321 has an opening that penetrates to the back side of the integrated semiconductor circuit device 300, and is connected to an Au-plated wiring formed over the entire surface of the back side. As a result, potential of all of the emitter electrodes 160 becomes equal to that of the plating provided on the back of the integrated semiconductor circuit device 300.

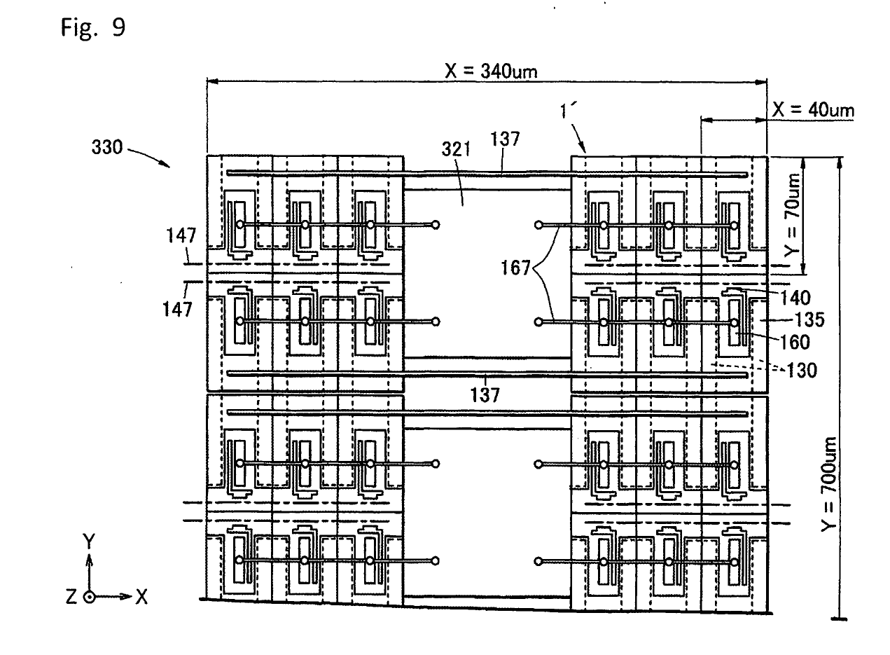

FIG. 9 is a top view showing in detail the HBTs disposed in the semiconductor device 330. The constitution of the semiconductor device 330 is the same as that of the semiconductor device 250′ according to the present invention. The HBT used in the semiconductor device 330 is the inverted mesa heterojunction bipolar transistor cell 1′. The HBT 1′ of the semiconductor device 330 has dimensions of 40 μm in X direction and 70 μm in Y direction, reversing the relation between the dimensions in X and Y directions from that of the HBT 1′ of the semiconductor device 320 (the area remains the same).

Three HBTs 1′ are disposed in the X direction on either side of the via hole electrode 321, six HBTs 1′ in all. Similarly to the case of the semiconductor device 320, the collective wiring 147 for the base current and the collective wiring 167 for the emitter current are also provided besides the collective wiring 137 for the collector current.

The first and second column counting from the top (from the distal end in Y direction) in FIG. 9 share the same via hole electrode 321 in common. The HBTs 1′ of both the first and second column are HBTs of inverted mesa type, although the HBT 1 in the second stage is rotated by 180 degrees from the position of the HBT 1 in the first column with the collective wirings 147 for the base current thereof being located near to each other.

Thus five sets in total, each set comprising two HBTs 1, namely ten HBTs 1′ are disposed in the longitudinal direction (Y direction) (only a part of which are shown in FIG. 9). In total, 60 HBTs 1′ of inverted mesa type are disposed in the semiconductor device 330.

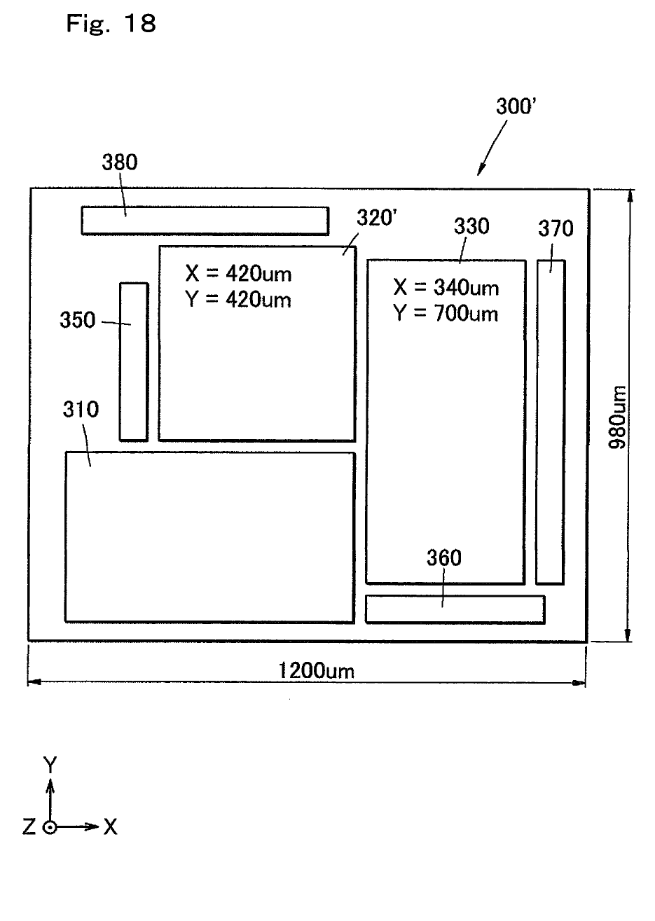

FIG. 18 shows an integrated semiconductor circuit device 300′ made by conventional technology for the purpose of comparison. In the integrated semiconductor circuit device 300′, since only the HBT 1′ of inverted mesa direction can be disposed, a semiconductor device 320′ constituted from inverted mesa HBTs 1′ is used instead of the semiconductor device 320 constituted from normal mesa HBTs 1. The integrated semiconductor circuit device 300′ is identical to the integrated semiconductor circuit device 300 except for the semiconductor device 320′.

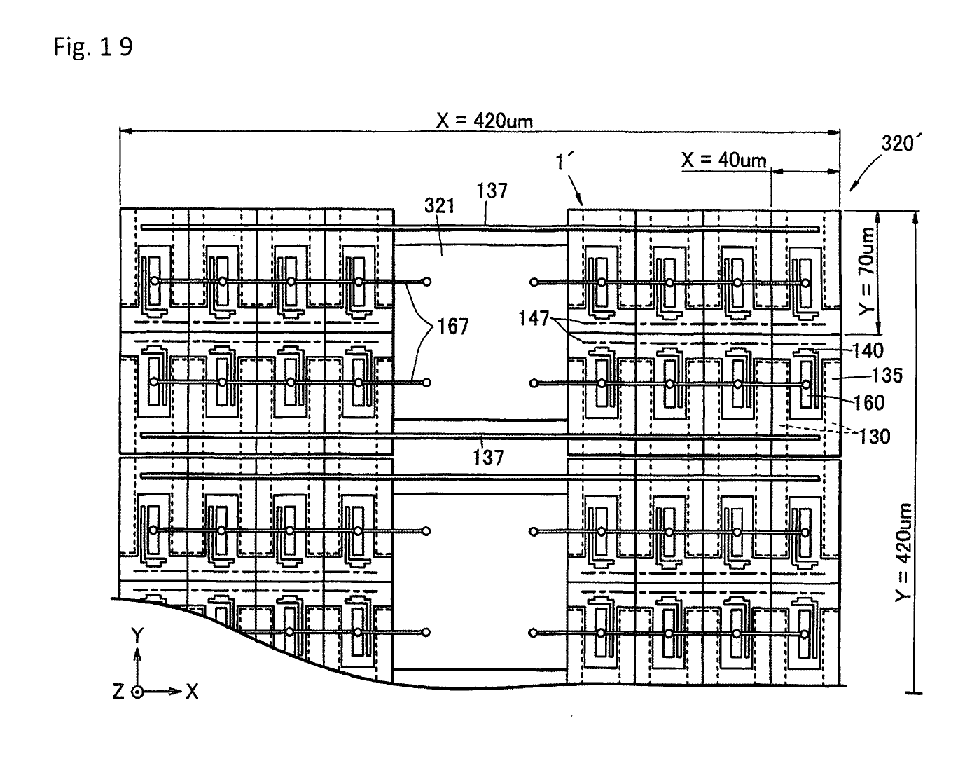

FIG. 19 is a top view showing in detail the semiconductor device 320′. Four HBTs 1′ are disposed in the X direction of FIG. 19 on either side of the via hole electrode 321, eight HBTs 1′ in all.

The first and second columns counting from the top (from the distal end in Y direction) in FIG. 9 share the same via hole electrode 321 in common. The HBTs 1′ of both the first and second columns are HBTs of inverted mesa type, although the HBT 1′ in the second column is rotated by 180 degrees from the position of the HBT 1′ in the first column with the collective wirings 147 for the base current thereof being located near to each other.

Thus three sets in total, each set comprising two HBTs 1, namely six HBTs 1′ are disposed in the longitudinal direction (Y direction) (only a part of which are shown in FIG. 19). In total, 48 HBTs 1′ of inverted mesa type are disposed in the semiconductor device 320′.

As a result, the semiconductor device 320′ has dimensions of 420 μm in X direction and 420 μm in Y direction, larger than the semiconductor device 320 by 80 μm in Y direction. This difference of 80 μm equals to the difference in the dimension in Y direction between the integrated semiconductor circuit device 300 and the integrated semiconductor circuit device 300′. While the semiconductor device 320′ is smaller than the semiconductor device 320 in X direction, there is a semiconductor device 310 that has large size in X direction as will be seen from FIG. 7 and FIG. 18. Accordingly, this difference does not cause a decrease in the direction in X direction of the integrated semiconductor circuit device 300′.

In the semiconductor device 320′, four HBTs 1′ are disposed in the X direction on either side of the via hole electrode 321, and therefore there is such a problem that the emitter of the fourth HBT 1′, that is the farthest from the via hole electrode 321, has a high resistance.

The emitter resistance may be decreased by disposing three HBTs 1′ in X direction on either side of the via hole electrode 321, six HBTs 1′ in total, disposing four sets, each set consisting of two HBTs 1′, in Y direction, eight HBTs 1′ in all, so as to dispose 48 HBTs 1′ in total.

With this method, however, the semiconductor device 320′ has dimension of 560 μm in Y direction, larger than the semiconductor device 320 by 220 μm. This means that the integrated semiconductor circuit device 300′ becomes larger than the integrated semiconductor circuit device 300 by 220 μm in the dimension in Y direction.

The inverted mesa HBT 1′ can be turned into normal mesa HBT 1B having a portion extending out of the trench provided on the lead-out wiring 135B of the semiconductor device 260 shown in FIG. 17, by conventional technology. In this case, six bipolar transistors 1B can be disposed in X direction, and eight bipolar transistors 1B can be disposed in Y direction, similarly to the case of the semiconductor device 320.

However, providing the portion extending out of the trench on the lead-out wiring 135B makes the bipolar transistor 1B larger by 10 μm apiece, and makes the semiconductor device 320 larger by 60 μm in X direction. This means that the integrated semiconductor circuit device 300 becomes larger by 60 μm in Y direction.

The integrated semiconductor circuit device 300 that uses the semiconductor device 320 constituted from the normal mesa HBTs 1 and the semiconductor device 330 constituted from the inverted mesa HBTs 1′ makes it possible to increase the degree of freedom in the layout and reduce the device area.

The bipolar transistor described in the embodiments above and the accompanying drawings has such a constitution as the sub-collector layer and the collector layer are provided at the bottom, the etching trench is formed in the collector layer and the emitter layer is provided on top of the base layer that is disposed over the collector layer.

However, the present invention can also be applied to a transistor cell having the overall constitution turned upside down, where a sub-emitter layer and the emitter layer are provided at the bottom, the etching trench is formed in the emitter layer and the collector layer is provided on top of the base layer disposed over the emitter layer. Naturally, a semiconductor device and an integrated semiconductor circuit device comprising transistor cells of such a constitution are also encompassed within the scope of the present invention.

This application is claiming priority of Japanese patent application No. 2007-255317 filed Sep. 28, 2007 under the benefits of the Paris Convention. The Japanese patent application No. 2007-255317 is incorporated herein by reference.

What is claimed is:

1. A semiconductor device comprising a plurality of transistor cells each comprising a first layer, a base layer and a second layer formed in this order on a substrate, one of said first layer and said second layer serving as a collector layer and the other serving as an emitter layer, a first electrode connected to said first layer of each of said transistor cells being formed in an etching trench formed in said first layer, wherein
said etching trench has normal mesa surface on the side along the longitudinal direction thereof, and said first electrodes of said plurality of transistor cells are connected each other through a collective wiring that is provided so as to cross said normal mesa surfaces of said trenches of said plurality of transistor cells.

2. A semiconductor device comprising a plurality of transistor cells each comprising a first layer, a base layer and a second layer formed in this order on a substrate, one of said first layer and said second layer serving as a collector layer and the other serving as an emitter layer, a first electrode connected to said first layer of each of said transistor cells being formed in an etching trench formed in said first layer, wherein
said etching trenches provided between adjacent transistor cells are connected each other thorough a second etching trench provided in said first layer, and said first electrodes provided between the plurality of transistor cells are connected each other through a second electrode disposed in said second etching trench.

3. The semiconductor device according to claim 1 or 2, wherein at least one of said substrate, said first layer, said base layer and said second layer is made of a compound semiconductor.

4. The semiconductor device according to claim 3, wherein said first layer is made of GaAs, and the longitudinal direction of said etching trench is parallel to [01-1] orientation of said first layer.

5. The semiconductor device according to any one of claims 1 to 4, wherein said first layer consists of collector layer and a sub-collector layer, said etching trench penetrates through said collector layer, and said first electrode contacts with said sub-contact layer.

6. An integrated semiconductor circuit device, comprising:
a first semiconductor device according to any one of claims 1 to 5; and
a second semiconductor device including a plurality of second transistor cells formed on the same substrate as that of said transistor cells of said first semiconductor device,
wherein said second transistor cells have an etching trench rotated by about 90 degrees in a plane parallel to the substrate relative to the etching trench of the transistor cells of said first semiconductor device.
